(19) United States
(12) Patent Application Publication
(10) Pub. No.: US 2026/0190313 A1
(43) Pub. Date: Jul. 2, 2026

(54) ELECTROMAGNETIC SHIELDING GRAPHENE COMPOSITE FILM AND METHOD OF PREPARING THE SAME

(71) Applicant: NATIONAL CHENG KUNG UNIVERSITY, Tainan City (TW)

(72) Inventors: I-WEN PETER CHEN, Tainan City (TW); YI-JUNG HUANG, Taichung City (TW); TING-YI YANG, Tainan City (TW)

(73) Assignee: NATIONAL CHENG KUNG UNIVERSITY, Tainan City (TW)

(21) Appl. No.: 19/234,226

(22) Filed: Jun. 10, 2025

(30) Foreign Application Priority Data
Dec. 30, 2024 (TW) 113151503

(51) Int. Cl. H05K 9/00; C01B 32/184

(52) U.S. Cl. CPC H05K 9/0081; C01B 32/184; C01B 2204/22; C01P 2002/72; C01P 2002/82; C01P 2006/40

(57) ABSTRACT

An electromagnetic shielding graphene composite film includes a graphene base material having a surface attached with a nano-metal oxide. The electromagnetic shielding graphene composite film shows an electromagnetic wave transmittance of no more than 60 dB and an electromagnetic wave reflectance that ranges from 0 to 10 dB in a frequency range of 5 to 15 GHz. This indicates that the graphene base material shows electromagnetic shielding performance. A method of preparing an electromagnetic shielding graphene composite film is also provided and includes steps of: immersing a metal plate in a graphene oxide solution to induce a reaction, wherein a graphene base material which is self-assembling is formed on the metal plate; removing the metal plate from the graphene oxide solution and delaminating the metal plate using dilute hydrochloric acid to separate the graphene base material from the metal plate; and obtaining the electromagnetic shielding graphene composite film.

### BACKGROUND OF THE INVENTION

### Technical Field

The present invention relates generally to reduced graphene oxide (rGO) technology, and more particularly to an electromagnetic shielding graphene composite film and a method of preparing the same.

### Description of Related Art

As high-tech electronic devices and systems rapidly develop, many high-tech electronic devices are seeking to reduce the size of the high-tech electronic devices to provide portability and ease of operation. In the development of electronic shielding materials, it is also necessary to develop new types of lightweight and thin electromagnetic shielding materials that could be integrated into high-tech electronic devices to reduce or eliminate electromagnetic interference in confined environments.

Currently, many companies are developing graphene films for use in electronic devices. The existing graphene film technology has not been proven to provide an effective electromagnetic shielding performance. Furthermore, a traditional method of preparing the graphene film typically involves mechanical exfoliation to obtain a layer of the graphene film, which not only result in low production efficiency but also consume significant process energy and cost. In addition, to optimize the traditional method of preparing the graphene film, some companies have developed a method that first uses an oxidizing agent to oxidize graphite into graphene oxide (GO) in a sheet form, followed by the addition of a reducing agent to chemically reduce graphene oxide (GO) into reduced graphene oxide (rGO), which is self-assembling. However, most reducing agents, such as hydrazine, hydrogen iodide, and strong alkalis, carry high toxicity risks that could cause environmental pollution and harm to operators. Furthermore, the reduced graphene oxide (rGO), which is self-assembling, tends to agglomerate, increasing the difficulty of processing.

### BRIEF SUMMARY OF THE INVENTION

In view of the above, the primary objective of the present invention is to provide an electromagnetic shielding graphene composite film and a method of preparing the electromagnetic shielding graphene composite film. The method of preparing the electromagnetic shielding graphene composite film omits a step of adding a chemical reducing agent. This reduces contamination of the processing environment by the chemical reducing agent and enhances the safety of the operation. The electromagnetic shielding graphene composite film shows excellent electromagnetic shielding performance and could be applied to a plurality of electronic devices to suppress electromagnetic interference.

The present invention provides an electromagnetic shielding graphene composite film including a graphene base material, wherein a surface of the graphene base material is attached with a nano-metal oxide. The electromagnetic shielding graphene composite film shows an electromagnetic wave transmittance of no more than 60 dB and an electromagnetic wave reflectance that ranges from 0 to 10 dB in a frequency range of 5 to 15 GHz.

The present invention further provides a method of preparing an electromagnetic shielding graphene composite film including steps of: S1. providing a graphene oxide solution; S2. immersing a metal plate in the graphene oxide solution to induce a spontaneous redox reaction, wherein a reaction time of the metal plate immersed in the graphene oxide solution does not exceed 12 hours, so that a surface of the metal plate comes into contact with graphene oxide in the graphene oxide solution, reducing the graphene oxide and thereby forming a graphene base material which is self-assembling; and S3. removing the metal plate from the graphene oxide solution and performing a delamination process on the graphene base material formed on the surface of the metal plate using dilute hydrochloric acid at a concentration of 3.75 wt %, which enables separation of the graphene base material from the metal plate; a surface of the graphene base material is attached with a nano-metal oxide, which is produced by an oxidation reaction of the metal plate, thereby obtaining the electromagnetic shielding graphene composite film; the electromagnetic shielding graphene composite film shows an electromagnetic wave transmittance of no more than 60 dB and an electromagnetic wave reflectance that ranges from 0 to 10 dB in a frequency range of 5 to 15 GHz.

The method of preparing the electromagnetic shielding graphene composite film utilizes the spontaneous redox reaction between the metal plate selected from iron or magnesium and the graphene oxide solution, thereby omitting the step of adding the chemical reducing agent to the graphene oxide solution. This reduces contamination of the processing environment by the chemical reducing agent and enhances the safety of the operation.

Moreover, the surface of the metal plate comes into contact with the graphene oxide, reducing the graphene oxide and thereby forming the graphene base material which is self-assembling. Performing the delamination process on the graphene base material formed on the metal plate using the dilute hydrochloric acid enable the complete separation of the graphene base material from the metal plate. The surface of the graphene base material is attached with the nano-metal oxide, which is produced by the oxidation reaction of the metal plate. The electromagnetic shielding graphene composite film is obtained. The graphene base material of the electromagnetic shielding graphene composite film, after undergoing electromagnetic wave shielding tests, has been confirmed to effectively block electromagnetic wave penetration and also exhibits the ability to reflect electromagnetic waves. In this way, the electromagnetic shielding graphene composite film could be applied to the electronic devices to suppress electromagnetic interference.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a flowchart of the method of preparing the electromagnetic shielding graphene composite film according to an embodiment of the present invention;

FIG. 2 is a flowchart of the method of preparing the electromagnetic shielding graphene composite film including the step P1 according to the embodiment of the present invention;

FIG. 3A is a Raman spectrum showing the results obtained when the nano-metal oxide is iron oxide or magnesium oxide, according to the embodiment of the present invention;

FIG. 3B is a Raman spectrum showing the results obtained when the nano-metal oxide is aluminum oxide, nickel oxide, tin oxide, manganese oxide, or copper oxide according to the embodiment of the present invention;

FIG. 4 is an XRD pattern showing the XRD results for the graphene oxide in the control group and the electromagnetic shielding graphene composite films including iron oxide in the experimental group 1 and the experimental group 2, according to the embodiment of the present invention;

FIG. 5A is a data graph showing the electromagnetic wave reflectance of the front surface and the back surface of the electromagnetic shielding graphene composite film including iron oxide of the experimental group 1, according to the embodiment of the present invention;

FIG. 5B is a data graph showing the electromagnetic wave transmittance of the front surface and the back surface of the electromagnetic shielding graphene composite film including iron oxide of the experimental group 1, according to the embodiment of the present invention;

FIG. 6A is a data graph showing the electromagnetic wave reflectance of the front surface and the back surface of the dried electromagnetic shielding graphene composite film including iron oxide of the experimental group 1′, according to the embodiment of the present invention;

FIG. 6B is a data graph showing the electromagnetic wave transmittance of the front surface and the back surface of the dried electromagnetic shielding graphene composite film including iron oxide of the experimental group 1′, according to the embodiment of the present invention;

FIG. 7A is a data graph showing the electromagnetic wave reflectance of the front surface and the back surface of the electromagnetic shielding graphene composite film including magnesium oxide of the experimental group 3, according to the embodiment of the present invention;

FIG. 7B is a data graph showing the electromagnetic wave transmittance of the front surface and the back surface of the electromagnetic shielding graphene composite film including magnesium oxide of the experimental group 3, according to the embodiment of the present invention;

FIG. 8A is a data graph showing the electromagnetic wave reflectance of the front surface and the back surface of the dried electromagnetic shielding graphene composite film including magnesium oxide of the experimental group 3′, according to the embodiment of the present invention;

FIG. 8B is a data graph showing the electromagnetic wave transmittance of the front surface and the back surface of the dried electromagnetic shielding graphene composite film including magnesium oxide of the experimental group 3′, according to the embodiment of the present invention.

### DETAILED DESCRIPTION OF THE INVENTION

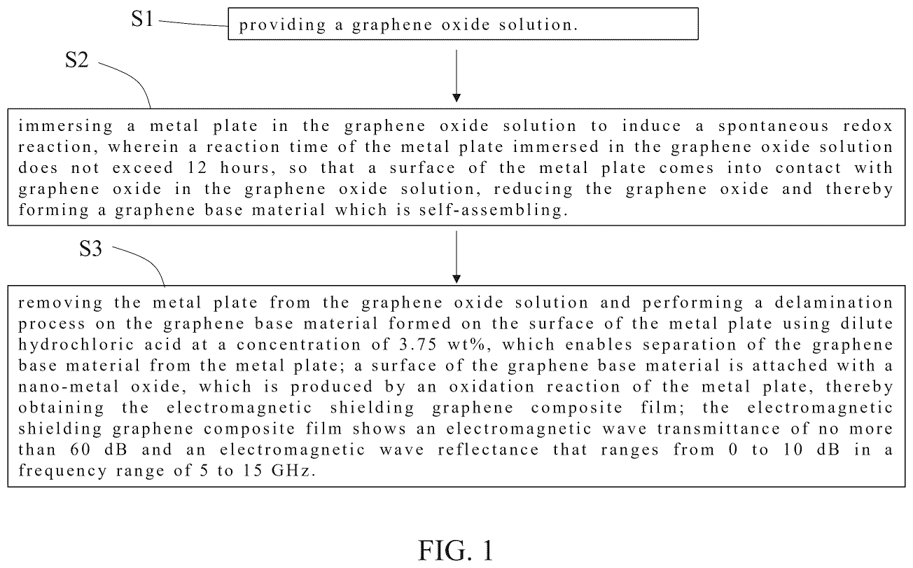

A method of preparing an electromagnetic shielding graphene composite film according to an embodiment of the present invention is illustrated in FIG. 1 and includes following steps:
Step S1: providing a graphene oxide solution, wherein a concentration of the graphene oxide solution ranges from 0.01 mg/ml to 50 mg/ml. In the current embodiment, the concentration of the graphene oxide solution ranges from 0.1 mg/ml to 25 mg/ml. In other embodiments, the concentration range of the graphene oxide solution might be adjusted as needed. When the concentration of the graphene oxide solution exceeds 50 mg/ml, the graphene oxide solution becomes overly concentrated, reducing a fluidity of the graphene oxide solution and causing the electromagnetic shielding graphene composite film to be prone to agglomeration after film formation. Conversely, when the concentration of the graphene oxide solution is lower than 0.01 mg/ml, a film formation time of the electromagnetic shielding graphene composite film is significantly prolonged, and a thickness of the electromagnetic shielding graphene composite film is reduced.

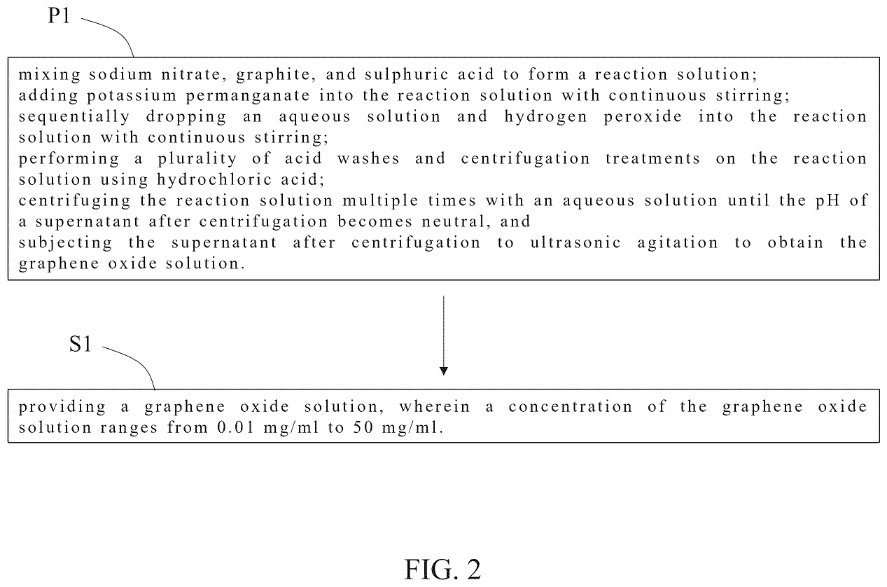

As shown in FIG. 2, in the current embodiment, a step P1 is also included before the step S1. In the step P1, first mixing sodium nitrate, graphite, and sulphuric acid to form a reaction solution. In the current embodiment, the reaction solution is prepared in proportions of 0.5-1.0 M of the sodium nitrate, 1.0-2.0 g of the graphite, and 25-30 mL of 18 M of a sulphuric acid solution. Maintaining continuous stirring of the sodium nitrate, the graphite, and the sulphuric acid under a temperature condition of 0° C. to 5° C. forms the reaction solution. Subsequently, adding potassium permanganate into the reaction solution with continuous stirring, wherein the potassium permanganate is quantitatively added in batches at least twice into the reaction solution, and a stirring time of the reaction solution is 10-12 hours. An amount of the potassium permanganate added to the reaction solution ranges from 5 to 10 g. Sequentially dropping an aqueous solution and hydrogen peroxide into the reaction solution with continuous stirring, wherein the hydrogen peroxide is added to the reaction solution to terminate an oxidation reaction of the graphite in the reaction solution. Following this, performing a plurality of acid washes and centrifugation treatments on the reaction solution using hydrochloric acid at a concentration of 37.5 wt %. Finally, centrifuging the reaction solution multiple times with an aqueous solution until the pH of a supernatant after centrifugation becomes neutral, and subjecting the supernatant after centrifugation to ultrasonic agitation to obtain the graphene oxide solution.

In other embodiments, the steps of the method of preparing the electromagnetic shielding graphene composite film might be adjust according to process requirements. For example, the graphene oxide solution provided in the step S1 is not limited to being obtained through the step P1, which means that the graphene oxide solution could be directly purchased. In this way, the step P1 could be omitted, as long as the step S1 of the method of preparing the electromagnetic shielding graphene composite film provides the graphene oxide solution.

Step S2: immersing a metal plate in the graphene oxide solution to induce a spontaneous redox reaction, wherein a reaction time of the metal plate immersed in the graphene oxide solution does not exceed 12 hours, with the reaction time being adjustable based on the concentration of the graphene oxide solution, ranging from a few minutes to 12 hours. In the current embodiment, the metal plate is selected from a group consisting of iron, magnesium, aluminum, nickel, tin, manganese, and copper. In an embodiment, the metal plate is selected from iron or magnesium, and a surface of the metal plate might be pre-polished. No reducing agent is added to the graphene oxide solution. Since graphene oxide in the graphene oxide solution includes oxygen functional groups, the graphene oxide possesses a relatively strong oxidation potential. When the surface of the metal plate comes into contact with the graphene oxide, a spontaneous redox reaction occurs, reducing the graphene oxide on the surface of the metal plate and thereby forming a graphene base material which is self-assembling.

Step S3: removing the metal plate from the graphene oxide solution and performing a delamination process on the graphene base material formed on the surface of the metal plate using dilute hydrochloric acid at a concentration of 3.75 wt %, which enables complete separation of the graphene base material from the metal plate, with a surface of the graphene base material remaining free of any damage or defects. Following the separation of the graphene base material from the metal plate, performing an acid wash using dilute hydrochloric acid at a concentration of 1.875 wt % for 2 to 12 hours removes impurities from the surface of the graphene base material. Subsequently, the graphene base material is dried. The surface of the graphene base material is attached with a nano-metal oxide, which is produced by an oxidation reaction of the metal plate, thereby obtaining the electromagnetic shielding graphene composite film. The nano-metal oxide is selected from a group consisting of iron oxide (Fe₂O₃), magnesium oxide (MgO), aluminum oxide (Al₂O₃), nickel oxide (NiO), tin oxide (SnO₂), manganese oxide (MnO₂), and copper oxide (CuO). In the current embodiment, the graphene base material includes a plurality of graphene sheets stacked together. A plurality of gaps is provided between the graphene sheets, so that the graphene base material forms the electromagnetic shielding graphene composite film which is porous. The nano-metal oxide which is produced by the oxidation reaction of the metal plate in the graphene oxide solution adheres to the gaps between the graphene sheets. A content of the nano-metal oxide in the electromagnetic shielding graphene composite film accounts for 0.001% to 20% by weight of a total content of the electromagnetic shielding graphene composite film.

Moreover, the electromagnetic shielding graphene composite film exhibits diffraction peaks in an X-ray diffraction (XRD) pattern at 2θ of 15°±3° and 25°±3°. A thickness of the graphene base material ranges from 1 μm to 2 mm. The electromagnetic shielding graphene composite film, after undergoing electromagnetic wave and conductivity tests, demonstrates an electromagnetic wave absorption performance in a frequency range of 5 to 15 GHz, with an electromagnetic wave transmittance no more than 60 dB, and an electromagnetic wave reflectance ranging from 0 to 10 dB. In an embodiment, the electromagnetic shielding graphene composite film demonstrates an electromagnetic wave absorption performance in a frequency range of 8 to 13 GHz, with an electromagnetic wave transmittance of 15 to 40 dB and an electromagnetic wave reflectance ranging from 0 to 2.5 dB. When the nano-metal oxide is iron oxide, the electromagnetic shielding graphene composite film exhibits an electrical conductivity ranging from 0.1 to 1000 S/cm. In an embodiment, the electromagnetic shielding graphene composite film exhibits an electrical conductivity ranging from 50 to 300 S/cm. When the nano-metal oxide is magnesium oxide, the electromagnetic shielding graphene composite film exhibits an electrical conductivity ranging from 0 to 750 S/cm.

Experimental results reveal that variations in the thickness of the graphene base material affect the electrical conductivity of the electromagnetic shielding graphene composite film. In the current embodiment, when the thickness of the graphene base material including iron oxide is 0.0029 mm, an electrical conductivity of the electromagnetic shielding graphene composite film is approximately 260 S/cm. When the thickness of the graphene base material including iron oxide is 0.031 mm, an electrical conductivity of the electromagnetic shielding graphene composite film is approximately 60 S/cm. When the thickness of the graphene base material including magnesium oxide is 0.003 mm, an electrical conductivity of the electromagnetic shielding graphene composite film is approximately 700 S/cm. When the thickness of the graphene base material including iron oxide is 0.096 mm, an electrical conductivity of the electromagnetic shielding graphene composite film is approximately 0.00003 S/cm.

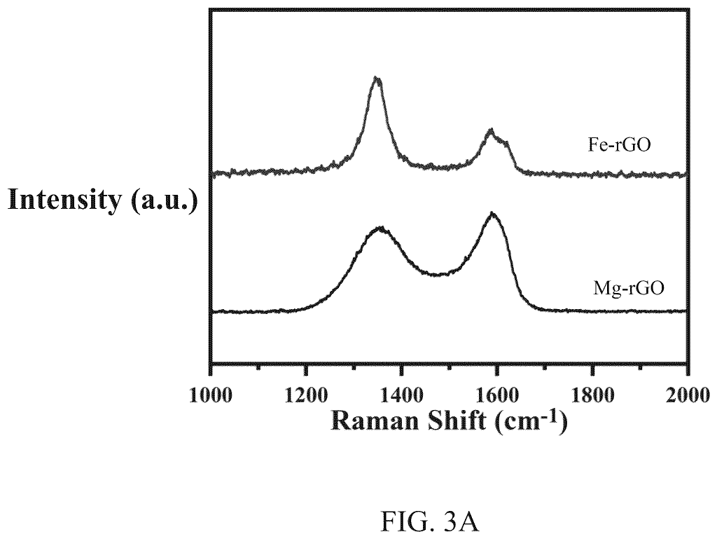

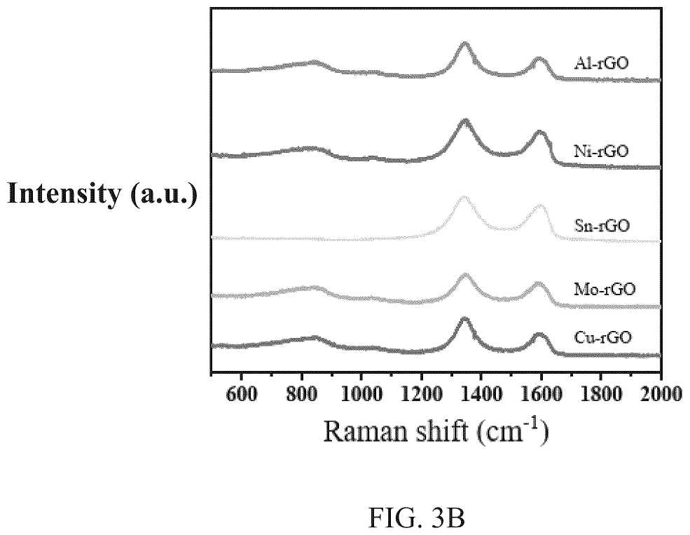

Moreover, the electromagnetic shielding graphene composite film exhibits a Raman spectrum that include a first peak located at 1300 cm⁻¹±100 and a second peak located at 1600 cm⁻¹±100. The electromagnetic shielding graphene composite film satisfies the following range: 0.6≤I_{D}/I_{G}≤3, wherein I_{D} is a peak intensity of the first peak, and I_{G} is a peak intensity of the second peak. In an embodiment, the electromagnetic shielding graphene composite film satisfies the following range: 0.8≤I_{D}/I_{G}≤2. FIG. 3A and FIG. 3B illustrate the corresponding Raman spectra when the nano-metal oxide is iron oxide (Fe₂O₃), magnesium oxide (MgO), aluminum oxide (Al₂O₃), nickel oxide (NiO), tin oxide (SnO₂), manganese oxide (MnO₂), or copper oxide (CuO). As shown in FIG. 3A, the electromagnetic shielding graphene composite film including iron oxide (Fe-rGO) shows I_{D}/I_{G}=1.2. The electromagnetic shielding graphene composite film including magnesium oxide (Mg-rGO) shows I_{D}/I_{G}=0.8. As shown in FIG. 3B, the electromagnetic shielding graphene composite film including aluminum oxide (Al-rGO) shows I_{D}/I_{G}=1.71. The electromagnetic shielding graphene composite film including nickel oxide (Ni-rGO) shows I_{D}/I_{G}=1.36. The electromagnetic shielding graphene composite film including tin oxide (Sn-rGO) shows I_{D}/I_{G}=1.25. The electromagnetic shielding graphene composite film including manganese oxide (Mo-rGO) shows I_{D}/I_{G}=1.22. The electromagnetic shielding graphene composite film including copper oxide (Cu-rGO) shows I_{D}/I_{G}=1.5.

Accordingly, the method of preparing the electromagnetic shielding graphene composite film utilizes the spontaneous redox reaction between the metal plate and the graphene oxide solution, thereby omitting a step of adding a chemical reducing agent to the graphene oxide solution. This reduces contamination of the processing environment by the chemical reducing agent and enhances the safety of the operation.

Moreover, the surface of the metal plate comes into contact with the graphene oxide, reducing the graphene oxide and thereby forming the graphene base material which is self-assembling. Performing the delamination process on the graphene base material formed on the surface of the metal plate using the dilute hydrochloric acid enable the complete separation of the graphene base material from the metal plate. The surface of the graphene base material is attached with the nano-metal oxide, which is produced by the oxidation reaction of the metal plate. The electromagnetic shielding graphene composite film, after undergoing electromagnetic wave shielding tests, has been confirmed to effectively block electromagnetic wave penetration and also exhibits the ability to reflect electromagnetic waves. In this way, the electromagnetic shielding graphene composite film could be applied to a plurality of electronic devices to suppress electromagnetic interference.

To fully understand a plurality of objectives, features, and effects of the present invention, a plurality of experimental groups and a control group are provided in the current embodiment, along with corresponding data of the experimental groups and the control group, including a plurality of X-ray diffraction (XRD) patterns and a plurality of graphs of electromagnetic wave transmission and reflection data.

1. Analysis of a plurality of diffraction peaks of the electromagnetic shielding graphene composite film prepared by using an iron metal plate:

(1) Preparation of the electromagnetic shielding graphene composite films for experimental group 1 and experimental group 2:

The control group: Preparing the graphene oxide, which could either be synthesized in-house according to the step P1, or obtained from Jiangsu XFNANO Materials Tech Co., Ltd.

The experimental group 1: In the step S2 of the method of preparing the electromagnetic shielding graphene composite film, immersing an iron metal plate in the graphene oxide solution to induce a spontaneous redox reaction, wherein a reaction time of the iron metal plate immersed in the graphene oxide solution does not exceed 12 hours. No reducing agent is added to the graphene oxide solution. Instead, a surface of the iron metal plate comes into contact with the graphene oxide, thus reducing the graphene oxide and forming the graphene base material which is self-assembling. Next, in the step S3, removing the iron metal plate from the graphene oxide solution and performing a delamination process on the graphene base material formed on the surface of the iron metal plate using dilute hydrochloric acid at a concentration of 3.75 wt % enable complete separation of the graphene base material from the iron metal plate, with a surface of the graphene base material remaining free of any damage or defects. Finally, the electromagnetic shielding graphene composite film including iron oxide is obtained.

The experimental group 2: In the step S2 of the method of preparing the electromagnetic shielding graphene composite film, immersing an iron metal plate in the graphene oxide solution to induce a spontaneous redox reaction, wherein a reaction time of the iron metal plate immersed in the graphene oxide solution does not exceed 12 hours. No reducing agent is added to the graphene oxide solution. Instead, a surface of the iron metal plate comes into contact with the graphene oxide, thus reducing the graphene oxide and forming the graphene base material which is self-assembling. Next, in the step S3, removing the iron metal plate from the graphene oxide solution and performing a delamination process on the graphene base material formed on the surface of the iron metal plate using dilute hydrochloric acid at a concentration of 3.75 wt % enable complete separation of the graphene base material from the iron metal plate, with a surface of the graphene base material remaining free of any damage or defects. Following the separation of the graphene base material from the iron metal plate, performing an acid wash using dilute hydrochloric acid at a concentration of 1.875 wt % for 2 to 12 hours removes impurities from the graphene base material. Finally, the electromagnetic shielding graphene composite film including iron oxide is obtained.

(2) Detection of the diffraction peaks of the electromagnetic shielding graphene composite film including iron oxide in the experimental group 1 and the experimental group 2.

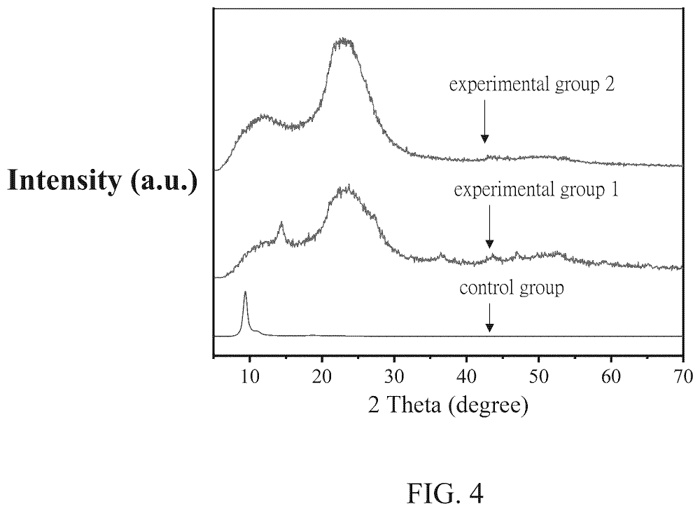

X-ray diffraction (XRD) testing is performed separately on the electromagnetic shielding graphene composite films including iron oxide from the experimental group 1 and the experimental group 2. In the current embodiment, a XRD instrument model used is Bruker D8 Advance. FIG. 4 illustrates a plurality of XRD results for the control group, the experimental group 1, and the experimental group 2. The control group exhibits a diffraction peak at 2θ of 10° in the X-ray diffraction (XRD) analysis. The experimental group 1 has diffraction peaks at 2θ of 15° and 24° in the XRD analysis. The experimental group 2 has diffraction peaks at 2θ of 13° and 24° in the XRD analysis and shows significantly reduced noise interference compared to the experimental group 1. This indicates that the method of preparing the electromagnetic shielding graphene composite film, which includes performing the acid washing process on the graphene base material using the dilute hydrochloric acid after the separation of the graphene base material from the iron metal plate in the step S3, effectively reduces the impurities on the graphene base material. Therefore, the diffraction peaks of the electromagnetic shielding graphene composite film in the XRD testing become more concentrated.

2. Analysis of an electromagnetic wave reflectance and an electromagnetic wave transmittance corresponding to the electromagnetic shielding graphene composite film including iron oxide, prepared by using the iron metal plate:

(1) Testing an electromagnetic wave absorption performance of the electromagnetic shielding graphene composite film including iron oxide of the experimental group 1, in order to detect the electromagnetic wave reflectance and the electromagnetic wave transmittance of a front surface and a back surface of the electromagnetic shielding graphene composite film.

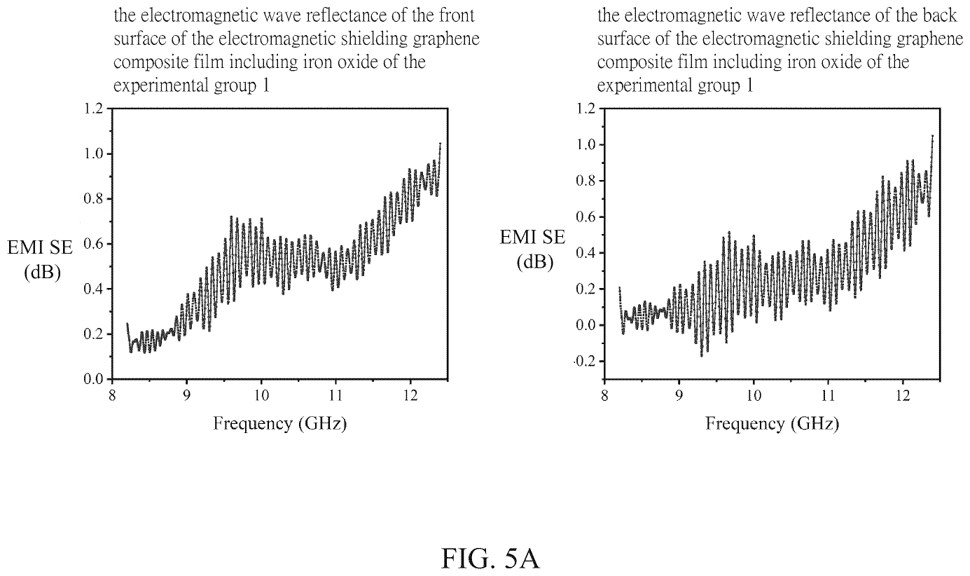

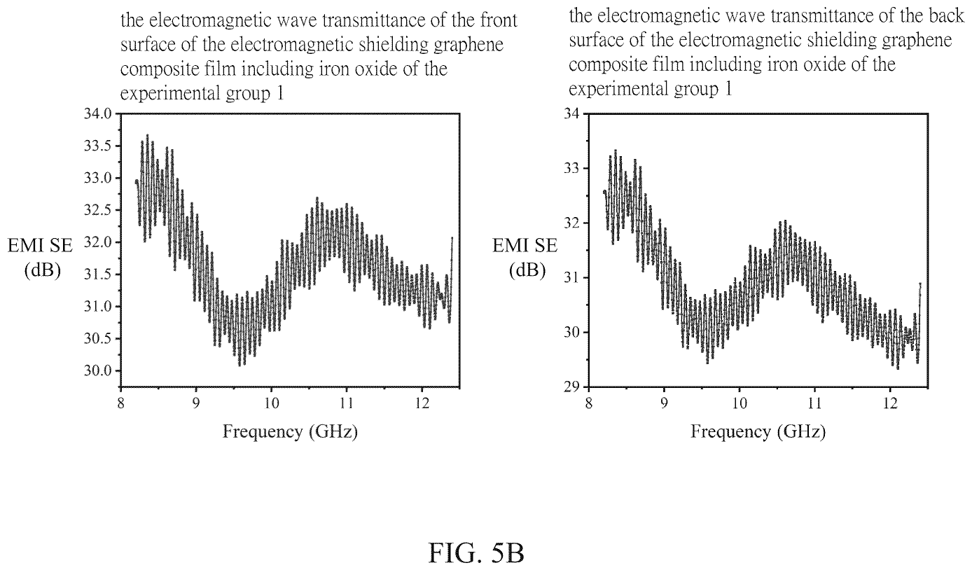

In the current embodiment, an equipment used to detect the electromagnetic wave reflectance and the electromagnetic wave transmittance of the electromagnetic shielding graphene composite films in each experimental group is Keysight E8364A. FIG. 5A shows the electromagnetic wave reflectance of the front surface and the back surface of the electromagnetic shielding graphene composite film including iron oxide of the experimental group 1. As shown in FIG. 5A, the front surface of the electromagnetic shielding graphene composite film including iron oxide of the experimental group 1 shows the electromagnetic wave reflectance that ranges from 0.1 to 1.0 dB in the frequency range of 8 to 13 GHz. Specifically, the front surface shows the electromagnetic wave reflectance that ranges from 0.1 to 0.2 dB in the frequency range of 8 to 9 GHz. The front surface shows the electromagnetic wave reflectance that ranges from 0.2 to 0.7 dB in the frequency range of 9 to 10 GHz. The front surface shows the electromagnetic wave reflectance that ranges from 0.4 to 0.7 dB in the frequency range of 10 to 11 GHz. The front surface shows the electromagnetic wave reflectance that ranges from 0.4 to 1.0 dB in the frequency range of 11 to 12 GHz. The back surface of the electromagnetic shielding graphene composite film including iron oxide of the experimental group 1 shows the electromagnetic wave reflectance that ranges from- 0.2 to 1.0 dB in the frequency range of 8 to 13 GHz. Specifically, the back surface shows the electromagnetic wave reflectance that ranges from- 0.1 to 0.2 dB in the frequency range of 8 to 9 GHz. The back surface shows the electromagnetic wave reflectance that ranges from- 0.2 to 0.5 dB in the frequency range of 9 to 10 GHz. The back surface shows the electromagnetic wave reflectance that ranges from 0 to 0.5 dB in the frequency range of 10 to 11 GHz. The back surface shows the electromagnetic wave reflectance that ranges from 0.5 to 1.0 dB in the frequency range of 11 to 12 GHz. In summary, the front surface and the back surface of the electromagnetic shielding graphene composite film including iron oxide of the experimental group 1 both provide higher electromagnetic wave reflectance in the frequency range of 11 to 12 GHz.

FIG. 5B shows the electromagnetic wave transmittance of the front surface and the back surface of the electromagnetic shielding graphene composite film including iron oxide of the experimental group 1. As shown in FIG. 5B, the front surface of the electromagnetic shielding graphene composite film including iron oxide of the experimental group 1 shows the electromagnetic wave transmittance that ranges from 30 to 34 dB in the frequency range of 8 to 13 GHz. Specifically, the front surface shows the electromagnetic wave transmittance that ranges from 31 to 33.5 dB in the frequency range of 8 to 9 GHz. The front surface shows the electromagnetic wave transmittance that ranges from 30.0 to 32.0 dB in the frequency range of 9 to 10 GHz. The front surface shows the electromagnetic wave transmittance that ranges from 30.5 to 32.5 dB in the frequency range of 10 to 11 GHz. The front surface shows the electromagnetic wave transmittance that ranges from 30.5 to 32.5 dB in the frequency range of 11 to 12 GHz. The back surface of the electromagnetic shielding graphene composite film including iron oxide of the experimental group 1 shows the electromagnetic wave transmittance that ranges from 29 to 34 dB in the frequency range of 8 to 13 GHz. Specifically, the back surface shows the electromagnetic wave transmittance that ranges from 29.5 to 33.5 dB in the frequency range of 8 to 9 GHz. The back surface shows the electromagnetic wave transmittance that ranges from 29.0 to 31.5 dB in the frequency range of 9 to 10 GHz. The back surface shows the electromagnetic wave transmittance that ranges from 30.0 to 32.0 dB in the frequency range of 10 to 11 GHz. The back surface shows the electromagnetic wave transmittance that ranges from 29.5 to 31.5 dB in the frequency range of 11 to 12 GHz. In summary, the front surface and the back surface of the electromagnetic shielding graphene composite film including iron oxide of the experimental group 1 provide higher impedance to electromagnetic wave transmission in the frequency range of 8 to 9 GHz. The front surface and the back surface could achieve the electromagnetic wave transmittance that ranges from 29 to 32 dB in the frequency range of 11 to 12 GHz.

(2) Testing an electromagnetic wave absorption performance of a dried electromagnetic shielding graphene composite film including iron oxide of an experimental group 1′, in order to detect an electromagnetic wave reflectance and an electromagnetic wave transmittance of a front surface and a back surface of the dried electromagnetic shielding graphene composite film including iron oxide.

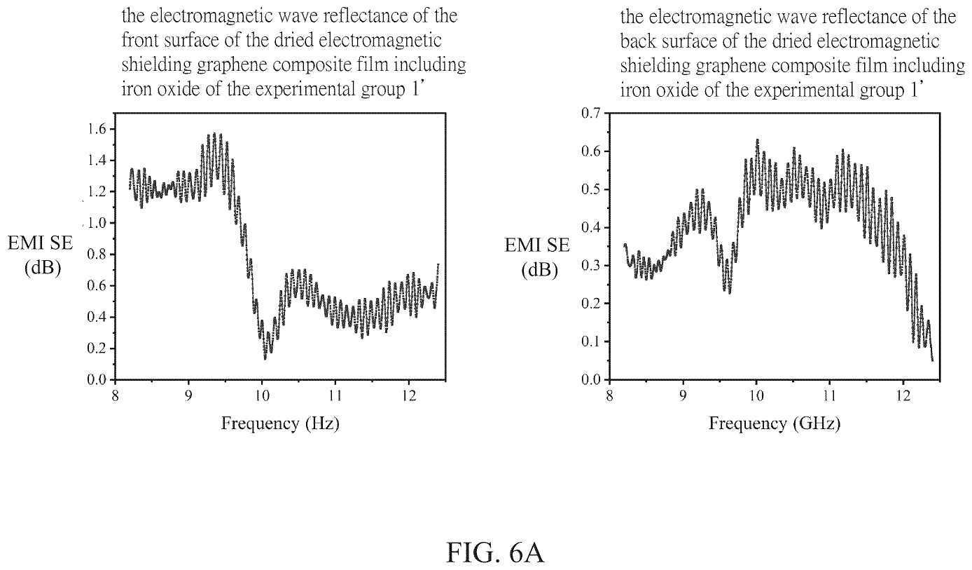

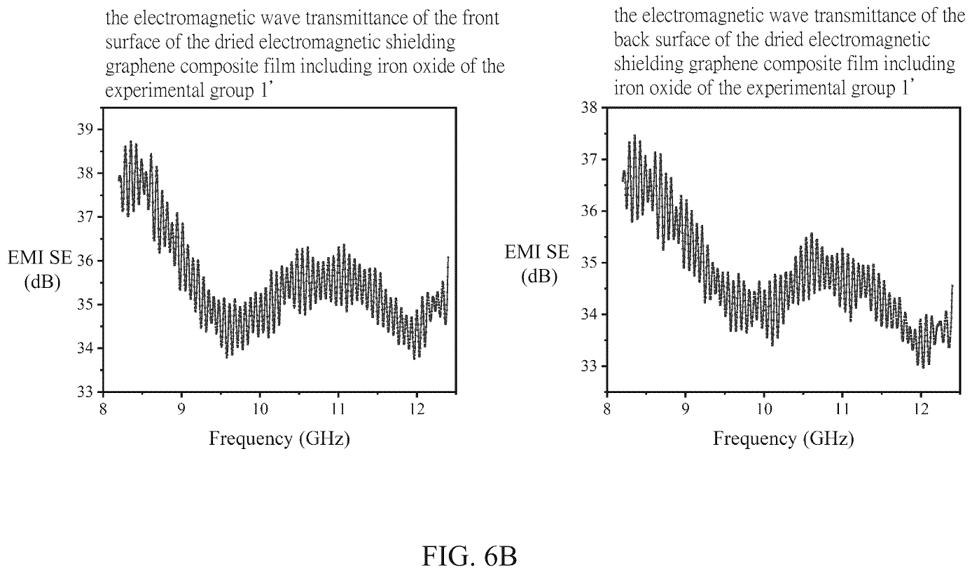

FIG. 6A shows the electromagnetic wave reflectance of the front surface and the back surface of the dried electromagnetic shielding graphene composite film including iron oxide of the experimental group 1′. The dried electromagnetic shielding graphene composite film including iron oxide of the experimental group 1′ is obtained by drying the electromagnetic shielding graphene composite film of the experimental group 1, wherein a drying process for the dried electromagnetic shielding graphene composite film might be performed by oven drying or freeze-drying, but is not limited thereto. As shown in FIG. 6A, the front surface of the dried electromagnetic shielding graphene composite film including iron oxide of the experimental group 1′ shows the electromagnetic wave reflectance that ranges from 0 to 1.6 dB in the frequency range of 8 to 13 GHz. Specifically, the front surface shows the electromagnetic wave reflectance that ranges from 1.1 to 1.4 dB in the frequency range of 8 to 9 GHz. The front surface shows the electromagnetic wave reflectance that ranges from 0.1 to 1.4 dB in the frequency range of 9 to 10 GHz. The front surface shows the electromagnetic wave reflectance that ranges from 0.1 to 0.7 dB in the frequency range of 10 to 11 GHz. The front surface shows the electromagnetic wave reflectance that ranges from 0.3 to 0.7 dB in the frequency range of 11 to 12 GHz. The back surface of the dried electromagnetic shielding graphene composite film including iron oxide of the experimental group 1′ shows the electromagnetic wave reflectance that ranges from 0 to 0.6 dB in the frequency range of 8 to 13 GHz. Specifically, the back surface shows the electromagnetic wave reflectance that ranges from 0.25 to 0.5 dB in the frequency range of 8 to 9 GHz. The back surface shows the electromagnetic wave reflectance that ranges from 0.2 to 0.65 dB in the frequency range of 9 to 10 GHz. The back surface shows the electromagnetic wave reflectance that ranges from 0.4 to 0.65 dB in the frequency range of 10 to 11 GHz. The back surface shows the electromagnetic wave reflectance that ranges from 0.1 to 0.6 dB in the frequency range of 11 to 12 GHz. In summary, the electromagnetic wave reflection performance of the front surface and the back surface of the dried electromagnetic shielding graphene composite film including iron oxide of the experimental group 1′ is significantly improved compared to that of the experimental group 1. In addition, the front surface of the dried electromagnetic shielding graphene composite film including iron oxide of the experimental group 1′ shows higher electromagnetic wave reflection performance in the frequency range of 8 to 9 GHz than in the frequency range of 11 to 12 GHz. The back surface of the dried electromagnetic shielding graphene composite film including iron oxide of the experimental group 1′ shows a higher electromagnetic wave reflectance in the frequency range of 8 to 11 GHz than in the frequency range of 11 to 12 GHz.

FIG. 6B shows the electromagnetic wave transmittance of the front surface and the back surface of the dried electromagnetic shielding graphene composite film including iron oxide of the experimental group 1′. As shown in FIG. 6B, the front surface of the dried electromagnetic shielding graphene composite film including iron oxide of the experimental group 1′ shows the electromagnetic wave transmittance that ranges from 33 to 39 dB in the frequency range of 8 to 13 GHz. Specifically, the front surface shows the electromagnetic wave transmittance that ranges from 35 to 39 dB in the frequency range of 8 to 9 GHz. The front surface shows the electromagnetic wave transmittance that ranges from 33.5 to 36.0 dB in the frequency range of 9 to 10 GHz. The front surface shows the electromagnetic wave transmittance that ranges from 34.0 to 36.0 dB in the frequency range of 10 to 11 GHz. The front surface shows the electromagnetic wave transmittance that ranges from 33.5 to 36.0 dB in the frequency range of 11 to 12 GHz. The back surface of the dried electromagnetic shielding graphene composite film including iron oxide of the experimental group 1′ shows the electromagnetic wave transmittance that ranges from 33 to 38 dB in the frequency range of 8 to 13 GHz. Specifically, the back surface shows the electromagnetic wave transmittance that ranges from 34.0 to 37.5 dB in the frequency range of 8 to 9 GHz. The back surface shows the electromagnetic wave transmittance that ranges from 33.5 to 36.0 dB in the frequency range of 9 to 10 GHz. The back surface shows the electromagnetic wave transmittance that ranges from 33.5 to 35.5 dB in the frequency range of 10 to 11 GHz. The back surface shows the electromagnetic wave transmittance that ranges from 33.0 to 35.0 dB in the frequency range of 11 to 12 GHz. In summary, the front surface and the back surface of the dried electromagnetic shielding graphene composite film including iron oxide of the experimental group 1′ provide higher impedance to electromagnetic wave transmission compared to those of the experimental group 1. Furthermore, the front surface of the dried electromagnetic shielding graphene composite film including iron oxide of the experimental group 1′ provides higher impedance to electromagnetic wave transmission in the frequency range of 8 to 9 GHz than in the frequency range of 11 to 12 GHz. The back surface of the dried electromagnetic shielding graphene composite film including iron oxide of the experimental group 1′ provides higher impedance to electromagnetic wave transmission in the frequency range of 8 to 9 GHz than in the frequency range of 11 to 12 GHz.

In summary, the electromagnetic shielding graphene composite film including iron oxide of the experimental group 1 effectively enhances electromagnetic wave reflectance and impedance to electromagnetic wave transmission in the frequency range of 8 to 13 GHz, thereby showing excellent electromagnetic shielding performance. The front surface and the back surface of the dried electromagnetic shielding graphene composite film including iron oxide of the experimental group 1′ effectively enhance electromagnetic wave reflectance and impedance to electromagnetic wave transmission. Therefore, the electromagnetic shielding graphene composite film including iron oxide shows excellent electromagnetic shielding performance and effectively reduces electromagnetic wave interference.

3. Analysis of an electromagnetic wave reflectance and an electromagnetic wave transmittance corresponding to the electromagnetic shielding graphene composite film prepared by using a magnesium metal plate:

(1) Testing an electromagnetic wave absorption performance of the electromagnetic shielding graphene composite film including magnesium oxide of an experimental group 3, in order to detect the electromagnetic wave reflectance and the electromagnetic wave transmittance of a front surface and a back surface of the electromagnetic shielding graphene composite film including magnesium oxide.

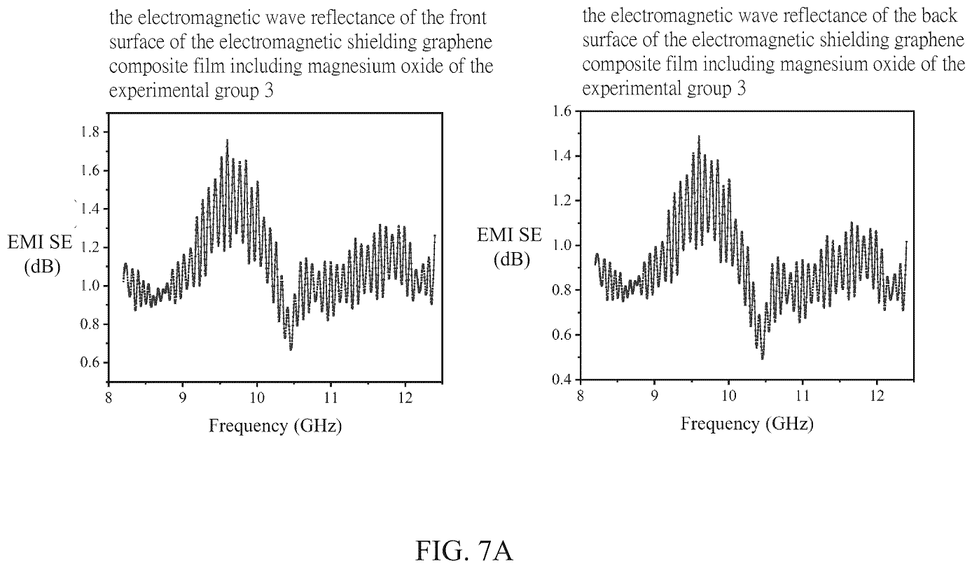

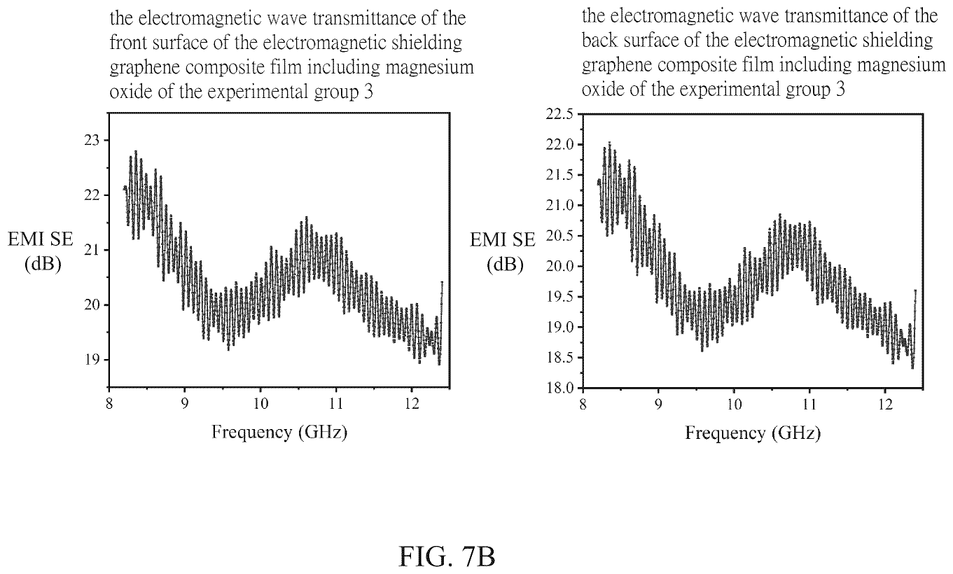

FIG. 7A shows the electromagnetic wave reflectance of the front surface and the back surface of the electromagnetic shielding graphene composite film including magnesium oxide of the experimental group 3. The experimental group 3 is prepared by using the magnesium metal plate, thus forming the electromagnetic shielding graphene composite film including magnesium oxide. A plurality of steps of the experimental group 3 is similar to the steps of the experimental group 1, and is therefore not repeated here. As shown in FIG. 7A, the front surface of the electromagnetic shielding graphene composite film including magnesium oxide of the experimental group 3 shows the electromagnetic wave reflectance that ranges from 0.6 to 1.8 dB in the frequency range of 8 to 13 GHz. Specifically, the front surface shows the electromagnetic wave reflectance that ranges from 0.8 to 1.2 dB in the frequency range of 8 to 9 GHz. The front surface shows the electromagnetic wave reflectance that ranges from 0.9 to 1.8 dB in the frequency range of 9 to 10 GHz. The front surface shows the electromagnetic wave reflectance that ranges from 0.6 to 1.4 dB in the frequency range of 10 to 11 GHz. The front surface shows the electromagnetic wave reflectance that ranges from 0.8 to 1.3 dB in the frequency range of 11 to 12 GHz. The back surface of the electromagnetic shielding graphene composite film including magnesium oxide of the experimental group 3 shows the electromagnetic wave reflectance that ranges from 0.5 to 1.5 dB in the frequency range of 8 to 13 GHz. Specifically, the back surface shows the electromagnetic wave reflectance that ranges from 0.7 to 1.0 dB in the frequency range of 8 to 9 GHz. The back surface shows the electromagnetic wave reflectance that ranges from 0.7 to 1.5 dB in the frequency range of 9 to 10 GHz. The back surface shows the electromagnetic wave reflectance that ranges from 0.5 to 1.3 dB in the frequency range of 10 to 11 GHz. The back surface shows the electromagnetic wave reflectance that ranges from 0.5 to 1.1 dB in the frequency range of 11 to 12 GHz. In summary, the front surface and the back surface of the electromagnetic shielding graphene composite film including magnesium oxide of the experimental group 3 both provide higher electromagnetic wave reflectance in the frequency range of 9 to 10 GHz. Moreover, the electromagnetic wave reflectance of the front surface and the back surface of the experimental group 3 is higher than the electromagnetic wave reflectance of the front surface and the back surface of the experimental group 1. This indicates that the electromagnetic shielding graphene composite film including magnesium oxide of the experimental group 3 shows higher electromagnetic wave reflection performance than the electromagnetic shielding graphene composite film including iron oxide of the experimental group 1.

FIG. 7B shows the electromagnetic wave transmittance of the front surface and the back surface of the electromagnetic shielding graphene composite film including magnesium oxide of the experimental group 3. As shown in FIG. 7B, the front surface of the electromagnetic shielding graphene composite film including magnesium oxide of the experimental group 3 shows the electromagnetic wave transmittance that ranges from 19 to 23 dB in the frequency range of 8 to 13 GHz. Specifically, the front surface shows the electromagnetic wave transmittance that ranges from 20.0 to 23.0 dB in the frequency range of 8 to 9 GHz. The front surface shows the electromagnetic wave transmittance that ranges from 19.0 to 21.0 dB in the frequency range of 9 to 10 GHz. The front surface shows the electromagnetic wave transmittance that ranges from 19.5 to 21.5 dB in the frequency range of 10 to 11 GHz. The front surface shows the electromagnetic wave transmittance that ranges from 19.0 to 21.0 dB in the frequency range of 11 to 12 GHz. The back surface of the electromagnetic shielding graphene composite film including magnesium oxide of the experimental group 3 shows the electromagnetic wave transmittance that ranges from 18 to 22 dB in the frequency range of 8 to 13 GHz. Specifically, the back surface shows the electromagnetic wave transmittance that ranges from 19.5 to 22.0 dB in the frequency range of 8 to 9 GHz. The back surface shows the electromagnetic wave transmittance that ranges from 18.5 to 20.5 dB in the frequency range of 9 to 10 GHz. The back surface shows the electromagnetic wave transmittance that ranges from 19.0 to 21.0 dB in the frequency range of 10 to 11 GHz. The back surface shows the electromagnetic wave transmittance that ranges from 18.5 to 20.5 dB in the frequency range of 11 to 12 GHz. In summary, the front surface and the back surface of the electromagnetic shielding graphene composite film including magnesium oxide of the experimental group 3 both provide higher impedance to electromagnetic wave transmission in the frequency range of 8 to 9 GHz. The electromagnetic wave transmittance of the front surface and the back surface of the experimental group 3 is lower than the electromagnetic wave transmittance of the front surface and the back surface of the experimental group 1. This indicates that the electromagnetic shielding graphene composite film including iron oxide of the experimental group 1 enhances the electromagnetic wave absorption, thereby reducing electromagnetic wave transmission compared to the electromagnetic shielding graphene composite film including magnesium oxide of the experimental group 3. Therefore, the experimental group 1 provides higher impedance to electromagnetic wave transmission.

(2) Testing an electromagnetic wave absorption performance of a dried electromagnetic shielding graphene composite film including magnesium oxide of an experimental group 3′, in order to detect an electromagnetic wave reflectance and an electromagnetic wave transmittance of a front surface and a back surface of the dried electromagnetic shielding graphene composite film including magnesium oxide.

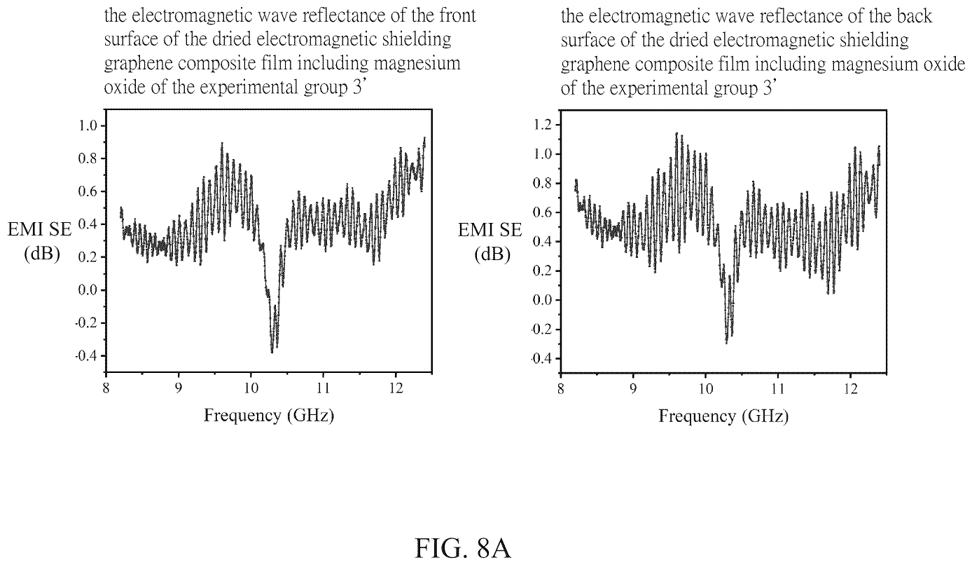

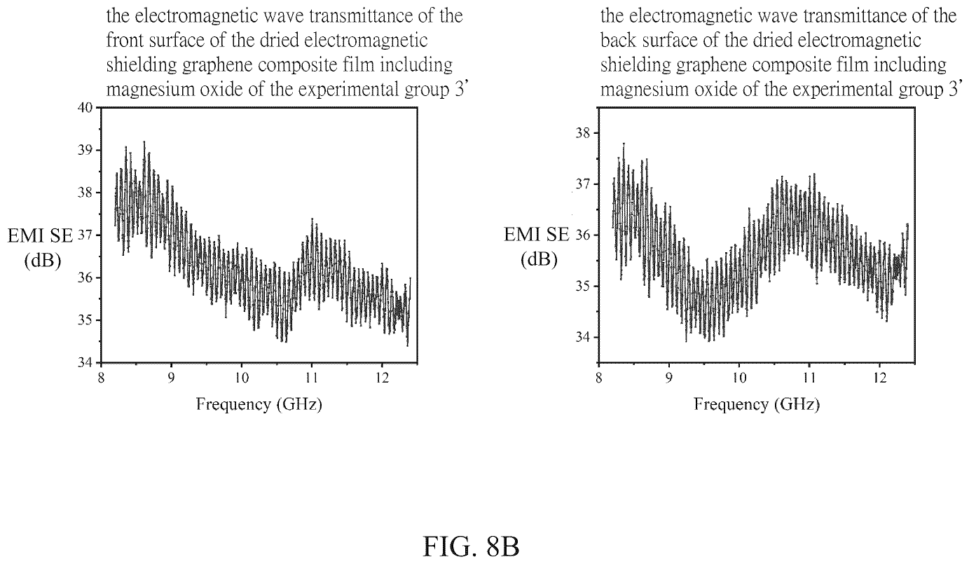

FIG. 8A shows the electromagnetic wave reflectance of the front surface and the back surface of the dried electromagnetic shielding graphene composite film including magnesium oxide of the experimental group 3′. The dried electromagnetic shielding graphene composite film including magnesium oxide of the experimental group 3′ is obtained by drying the electromagnetic shielding graphene composite film including magnesium oxide of the experimental group 3. As shown in FIG. 8A, the front surface of the dried electromagnetic shielding graphene composite film including magnesium oxide of the experimental group 3′ shows the electromagnetic wave reflectance that ranges from −0.4 to 1.0 dB in the frequency range of 8 to 13 GHz. Specifically, the front surface shows the electromagnetic wave reflectance that ranges from 0.1 to 0.5 dB in the frequency range of 8 to 9 GHz. The front surface shows the electromagnetic wave reflectance that ranges from 0.1 to 0.9 dB in the frequency range of 9 to 10 GHz. The front surface shows the electromagnetic wave reflectance that ranges from −0.4 to 0.7 dB in the frequency range of 10 to 11 GHz. The front surface shows the electromagnetic wave reflectance that ranges from 0.2 to 0.7 dB in the frequency range of 11 to 12 GHz. The back surface of the dried electromagnetic shielding graphene composite film including magnesium oxide of the experimental group 3′ shows the electromagnetic wave reflectance that ranges from −0.3 to 1.2 dB in the frequency range of 8 to 13 GHz. Specifically, the back surface shows the electromagnetic wave reflectance that ranges from 0.3 to 0.9 dB in the frequency range of 8 to 9 GHz. The back surface shows the electromagnetic wave reflectance that ranges from 0.2 to 1.2 dB in the frequency range of 9 to 10 GHz. The back surface shows the electromagnetic wave reflectance that ranges from −0.3 to 1.0 dB in the frequency range of 10 to 11 GHz. The back surface shows the electromagnetic wave reflectance that ranges from 0.1 to 1.1 dB in the frequency range of 11 to 12 GHz. In summary, the front surface and the back surface of the dried electromagnetic shielding graphene composite film including magnesium oxide of the experimental group 3′ clearly show lower electromagnetic wave reflection performance than the front surface and the back surface of the electromagnetic shielding graphene composite film including magnesium oxide of the experimental group 3. This indicates that the dried electromagnetic shielding graphene composite film including magnesium oxide instead leads to a significant reduction in electromagnetic wave reflection efficiency.

FIG. 8B shows the electromagnetic wave transmittance of the front surface and the back surface of the dried electromagnetic shielding graphene composite film including magnesium oxide of the experimental group 3′. As shown in FIG. 8B, the front surface of the dried electromagnetic shielding graphene composite film including magnesium oxide of the experimental group 3′ shows the electromagnetic wave transmittance that ranges from 34 to 39 dB in the frequency range of 8 to 13 GHz. Specifically, the front surface shows the electromagnetic wave transmittance that ranges from 36.0 to 39.0 dB in the frequency range of 8 to 9 GHz. The front surface shows the electromagnetic wave transmittance that ranges from 35.0 to 38.0 dB in the frequency range of 9 to 10 GHz. The front surface shows the electromagnetic wave transmittance that ranges from 34.5 to 37.5 dB in the frequency range of 10 to 11 GHz. The front surface shows the electromagnetic wave transmittance that ranges from 34.5 to 37.5 dB in the frequency range of 11 to 12 GHz. The back surface of the dried electromagnetic shielding graphene composite film including magnesium oxide of the experimental group 3′ shows the electromagnetic wave transmittance that ranges from 34 to 38 dB in the frequency range of 8 to 13 GHz. Specifically, the back surface shows the electromagnetic wave transmittance that ranges from 34.5 to 38.0 dB in the frequency range of 8 to 9 GHz. The back surface shows the electromagnetic wave transmittance that ranges from 34.0 to 36.0 dB in the frequency range of 9 to 10 GHz. The back surface shows the electromagnetic wave transmittance that ranges from 34.5 to 37.0 dB in the frequency range of 10 to 11 GHz. The back surface shows the electromagnetic wave transmittance that ranges from 34.5 to 37.5 dB in the frequency range of 11 to 12 GHz. In summary, the front surface and the back surface of the dried electromagnetic shielding graphene composite film including magnesium oxide of the experimental group 3′ provide higher impedance to electromagnetic wave transmission compared to those of the experimental group 3. Moreover, the electromagnetic wave transmittance of the front surface and the back surface of the experimental group 3′ shows no significant difference compared to the electromagnetic wave transmittance of the front surface and the back surface of the experimental group 1′.

In summary, the electromagnetic shielding graphene composite film including magnesium oxide of the experimental group 3 provides higher electromagnetic wave reflection performance and higher impedance to electromagnetic wave transmission in the frequency range of 8 to 13 GHz. The dried electromagnetic shielding graphene composite film including magnesium oxide of the experimental group 3′ significantly reduces the electromagnetic wave reflection efficiency on both the front surface and back surface, and enhances the impedance to electromagnetic wave transmission. Therefore, the dried electromagnetic shielding graphene composite film including magnesium oxide shows excellent electromagnetic shielding performance and effectively reduces electromagnetic wave interference.

It is noteworthy that the electromagnetic wave absorption performance of the electromagnetic shielding graphene composite film is demonstrated using embodiments including iron oxide and magnesium oxide, but is not limited thereto. In other embodiments, the electromagnetic shielding graphene composite film includes aluminum oxide, nickel oxide, tin oxide, manganese oxide, or copper oxide, and the measured electromagnetic wave absorption performance similarly achieves the effect of suppressing electromagnetic interference.

It must be pointed out that the embodiments described above are only some preferred embodiments of the present invention. All equivalent structures and methods which employ the concepts disclosed in this specification and the appended claims should fall within the scope of the present invention.

What is claimed is:

1. An electromagnetic shielding graphene composite film, comprising:
a graphene base material, wherein a surface of the graphene base material is attached with a nano-metal oxide;
wherein the electromagnetic shielding graphene composite film shows an electromagnetic wave transmittance of no more than 60 dB and an electromagnetic wave reflectance that ranges from 0 to 10 dB in a frequency range of 5 to 15 GHz.

2. The electromagnetic shielding graphene composite film as claimed in claim 1, wherein the electromagnetic shielding graphene composite film shows an electromagnetic wave transmittance that ranges from 15 to 40 dB in a frequency range of 8 to 13 GHz; a thickness of the graphene base material ranges from 1 μm to 2 mm.

3. The electromagnetic shielding graphene composite film as claimed in claim 1, wherein the nano-metal oxide is selected from a group consisting of iron oxide, magnesium oxide, aluminum oxide, nickel oxide, tin oxide, manganese oxide, and copper oxide.

4. The electromagnetic shielding graphene composite film as claimed in claim 2, wherein the nano-metal oxide is selected from a group consisting of iron oxide, magnesium oxide, aluminum oxide, nickel oxide, tin oxide, manganese oxide, and copper oxide.

5. The electromagnetic shielding graphene composite film as claimed in claim 3, wherein the electromagnetic shielding graphene composite film shows a Raman spectrum that comprise a first peak located at 1300 cm⁻¹±100 and a second peak located at 1600 cm⁻¹±100 ; the electromagnetic shielding graphene composite film satisfies the following range: 0.6≤I_{D}/I_{G}≤3, wherein I_{D} is a peak intensity of the first peak, and I_{G} is a peak intensity of the second peak.

6. The electromagnetic shielding graphene composite film as claimed in claim 4, wherein the electromagnetic shielding graphene composite film shows a Raman spectrum that comprise a first peak located at 1300 cm⁻¹±100 and a second peak located at 1600 cm⁻¹±100; the electromagnetic shielding graphene composite film satisfies the following range: 0.6≤I_{D}/I_{G}≤3, wherein I_{D} is a peak intensity of the first peak, and I_{G} is a peak intensity of the second peak.

7. The electromagnetic shielding graphene composite film as claimed in claim 3, wherein the electromagnetic shielding graphene composite film exhibits an electrical conductivity that ranges from 0.1 to 1000 S/cm when the nano-metal oxide is iron oxide; the electromagnetic shielding graphene composite film exhibits an electrical conductivity that ranges from 0 to 750 S/cm when the nano-metal oxide is magnesium oxide.

8. The electromagnetic shielding graphene composite film as claimed in claim 4, wherein the electromagnetic shielding graphene composite film exhibits an electrical conductivity that ranges from 0.1 to 1000 S/cm when the nano-metal oxide is iron oxide; the electromagnetic shielding graphene composite film exhibits an electrical conductivity that ranges from 0 to 750 S/cm when the nano-metal oxide is magnesium oxide.

9. The electromagnetic shielding graphene composite film as claimed in claim 3, wherein the electromagnetic shielding graphene composite film exhibits a plurality of diffraction peaks in an X-ray diffraction (XRD) pattern at 2θ of 15°±3° and 25°±3°.

10. The electromagnetic shielding graphene composite film as claimed in claim 4, wherein the electromagnetic shielding graphene composite film exhibits a plurality of diffraction peaks in an X-ray diffraction (XRD) pattern at 2θ of 15°±3° and 25°±3°.

11. The electromagnetic shielding graphene composite film as claimed in claim 1, wherein a content of the nano-metal oxide in the electromagnetic shielding graphene composite film accounts for 0.001% to 20% by weight of a total content of the electromagnetic shielding graphene composite film.

12. A method of preparing an electromagnetic shielding graphene composite film, comprising steps of:
S1. providing a graphene oxide solution;
S2. immersing a metal plate in the graphene oxide solution to induce a spontaneous redox reaction, wherein a reaction time of the metal plate immersed in the graphene oxide solution does not exceed 12 hours, so that a surface of the metal plate comes into contact with graphene oxide in the graphene oxide solution, reducing the graphene oxide and thereby forming a graphene base material which is self-assembling; and
S3. removing the metal plate from the graphene oxide solution and performing a delamination process on the graphene base material formed on the surface of the metal plate using dilute hydrochloric acid at a concentration of 3.75 wt %, which enables separation of the graphene base material from the metal plate; a surface of the graphene base material is attached with a nano-metal oxide, which is produced by an oxidation reaction of the metal plate, thereby obtaining the electromagnetic shielding graphene composite film; the electromagnetic shielding graphene composite film shows an electromagnetic wave transmittance of no more than 60 dB and an electromagnetic wave reflectance that ranges from 0 to 10 dB in a frequency range of 5 to 15 GHz.

13. The method as claimed in claim 12, further comprising a step P1 before the step S1, wherein the step P1 comprises:
mixing sodium nitrate, graphite, and sulphuric acid to form a reaction solution;
adding potassium permanganate into the reaction solution with continuous stirring;
sequentially dropping an aqueous solution and hydrogen peroxide into the reaction solution with continuous stirring;
performing a plurality of acid washes and centrifugation treatments on the reaction solution using hydrochloric acid;
centrifuging the reaction solution multiple times with an aqueous solution until the pH of a supernatant after centrifugation becomes neutral, and
subjecting the supernatant after centrifugation to ultrasonic agitation to obtain the graphene oxide solution.

14. The method as claimed in claim 13, wherein the sodium nitrate, the graphite, and the sulphuric acid are stirred under a temperature condition of 0° C. to 5° C. to form the reaction solution in the step P1; the potassium permanganate is quantitatively added in batches at least twice into the reaction solution, and a stirring time of the reaction solution is 10-12 hours in the step P1; a concentration of the graphene oxide solution ranges from 0.01 mg/ml to 50 mg/ml.

15. The method as claimed in claim 12, wherein no reducing agent is added to the graphene oxide solution in the step S2; the metal plate is selected from a group consisting of iron, magnesium, aluminum, nickel, tin, manganese, and copper in the step S2; in the step S3, following the separation of the graphene base material from the metal plate, performing an acid wash using dilute hydrochloric acid at a concentration of 1.875 wt % for 2 to 12 hours; the nano-metal oxide is selected from a group consisting of iron oxide, magnesium oxide, aluminum oxide, nickel oxide, tin oxide, manganese oxide, and copper oxide in the step S3.

16. The method as claimed in claim 15, wherein the electromagnetic shielding graphene composite film exhibits an electrical conductivity that ranges from 0.1 to 1000 S/cm when the nano-metal oxide is iron oxide; the electromagnetic shielding graphene composite film exhibits an electrical conductivity that ranges from 0 to 750 S/cm when the nano-metal oxide is magnesium oxide.

17. The method as claimed in claim 15, wherein the electromagnetic shielding graphene composite film shows a Raman spectrum that comprise a first peak located at 1300 cm⁻¹±100 and a second peak located at 1600 cm⁻¹±100; the electromagnetic shielding graphene composite film satisfies the following range: 0.6≤I_{D}/I_{G}≤3, wherein I_{D} is a peak intensity of the first peak, and I_{G} is a peak intensity of the second peak.

18. The method as claimed in claim 15, wherein the electromagnetic shielding graphene composite film exhibits a plurality of diffraction peaks in an X-ray diffraction (XRD) pattern at 2θ of 15°±3° and 25°±3°.
